(19) United States
(12) Patent Application Publication
(10) Pub. No.: US 2013/0209666 A1
(43) Pub. Date: Aug. 15, 2013

(54) EVAPORATING APPARATUS AND EVAPORATING METHOD

(71) Applicants: Tomiko Kamada, Sendai (JP); Hiraku Ishikawa, Sendai (JP); Yuji Ono, Oshu (JP); Teruyuki Hayashi, Nirasaki (JP); Takashi Fuse, Nirasaki (JP); Misako Saito, Nirasaki (JP); Toyohiro Kamada, Sendai (JP); Shimon Otsuki, Sendai (JP)

(72) Inventors: Tomiko Kamada, Sendai (JP); Hiraku Ishikawa, Sendai (JP); Yuji Ono, Oshu (JP); Teruyuki Hayashi, Nirasaki (JP); Takashi Fuse, Nirasaki (JP); Misako Saito, Nirasaki (JP); Toyohiro Kamada, Sendai (JP); Shimon Otsuki, Sendai (JP)

(73) Assignee: TOKYO ELECTRON LIMITED, Tokyo (JP)

(21) Appl. No.: 13/818,406

(22) PCT Filed: Aug. 24, 2011
(86) PCT No.: PCT/JP2011/069027

§ 371 Date: May 1, 2013

(30) Foreign Application Priority Data
Aug. 25, 2010 (JP) 2010-188101

(51) Int. Cl. H05B 33/10

(52) U.S. Cl. CPC H05B 33/10
USPC 427/8

(57) ABSTRACT

An evaporating method is capable of forming a thin film on a substrate by a vapor deposition process. The evaporating method includes measuring a vapor concentration of a material gas discharged to the substrate by a detector; and controlling a film forming condition based on a measurement result from the detector.

### TECHNICAL FIELD

The present disclosure relates to an evaporating apparatus and an evaporating method of forming a light emitting layer when manufacturing, e.g., an organic EL device.

### BACKGROUND ART

Recently, an organic EL (Electro Luminescence) device using EL is under development. Since the organic EL device is self-luminous, power consumption is low. Further, the organic EL device has a wider view angle than, e.g., a liquid crystal display (LCD). Due of these advantages, the organic EL device is expected to be further developed in the future.

Basically, the organic EL device has a sandwich structure including an anode (positive electrode), a light emitting layer and a cathode (negative electrode) that are stacked in this sequence on a glass substrate. In order to emit light of the light emitting layer, a transparent electrode made of, e.g., ITO (Indium Tin oxide) is used as the anode layer on the glass substrate. In general, such an organic EL device may be manufactured through the process of forming a light emitting layer and a cathode layer in this sequence on a glass substrate on which an ITO layer (anode layer) is previously formed, and, then, additionally forming a sealing film layer on the resultant structure.

In general, an organic layer in the organic EL device may be formed in an evaporating apparatus. In the evaporating apparatus, it is required to control a thickness of the organic layer or the like to a required thickness in order to improve light emitting efficiency or the like. For the purpose, various film thickness control methods have been proposed conventionally.

As a film thickness control method, there is known a film thickness measurement method as described in, for example, Patent Document 1. In this method, a film thickness is measured by using a quartz crystal microbalance as a measuring device, and a measurement result is reflected on a substrate on which a film formation is being actually performed. FIG. 1 is a diagram schematically illustrating an evaporating apparatus 100 configured to measure a film thickness by using a quartz crystal microbalance, as a conventional technique for general film thickness control. The evaporating apparatus 100 includes a chamber 101 and a substrate processing chamber 102 that are formed to communicate with each other. Within the evaporating apparatus 100, there is provided an evaporating head 110 communicating with a material gas supply unit 103. In a bottom portion of the substrate processing chamber 102, a substrate G is supported on a substrate supporting table 111 in a face-up state. Further, a quartz crystal microbalance (QCM) 112 made of, e.g., quartz is disposed to be adjacent to the substrate G on the substrate supporting table 111.

A bottom surface of the evaporating head 110 is opened, and this opening faces a top surface of the substrate G. The material gas supplied from the material gas supply unit 103 passes through the evaporating head 110 and is discharged onto the top surface of the substrate G from the opening of the evaporating head 110. At this time, the material gas is also discharged to the quartz crystal microbalance (QCM) 112 from the evaporating head 110. Further, an inside of the chamber 101 is set to be in a vacuum state by a vacuum pump 115 which communicates with the chamber 101 through an exhaust line 113, and, accordingly, the inside of the substrate processing chamber 102 communicating with the chamber 101 is also maintained in a vacuum state. Further, the evaporating head 110, the chamber 101 and the like are controlled by a non-illustrated heater to a temperature at which the material gas is not precipitated.

In the evaporating apparatus 100 having the above-described configuration, by measuring a thickness of a thin film actually deposited on the quartz crystal microbalance (QCM) 112, a thickness of a thin film deposited on the substrate G is measured and controlled. That is, under the same deposition conditions, there may be a certain relationship between the thicknesses of the thin films deposited on the quartz crystal microbalance (QCM) 112 and the substrate G. Thus, the thickness of the thin film deposited on the substrate G may be calculated from the thickness of the thin film deposited on the quartz crystal microbalance (QCM) 112 under the same conditions. Further, besides the quartz crystal microbalance (QCM) 112, also known as a target object for use in measuring a film thickness is, for example, a dummy substrate on which film formation is performed under substantially the same conditions as those for the substrate G on which film formation is actually performed.
Patent Document 1: Japanese Patent Laid-open Publication No. 2008-122200

### DISCLOSURE OF THE INVENTION

### Problems to be Solved by the Invention

Since, however, there is a limit in measuring the thickness of the thin film deposited on the quartz crystal microbalance (QCM) 112 in the above-described evaporating apparatus 100 (because the quartz crystal microbalance (QCM) 112 has a finite lifetime), the quartz crystal microbalance (QCM) 112 needs to be replaced frequently. Further, it is required to define a relationship between a film thickness on the quartz crystal microbalance (QCM) 112 and a film thickness on the substrate G by measuring the film thickness on the quartz crystal microbalance (QCM) 112 after performing deposition without the substrate G, and then, by measuring the film thickness on the substrate G after performing deposition on the substrate G under the same condition. Thus, it takes a long time to measure the film thickness, resulting in deterioration of productivity.

In view of the foregoing problems, the present illustrative embodiments provide an evaporating apparatus and an evaporating method capable of forming a thin film on a substrate G while concurrently controlling a thickness of the thin film.

### Means for Solving the Problems

In accordance with one aspect of an illustrative embodiment, there is provided an evaporating apparatus of forming a thin film on a substrate by a vapor deposition process. The evaporating apparatus includes a material supplying unit that is capable of being depressurized and is configured to supply a material gas; a film forming unit configured to form the thin film on the substrate; a detector that is provided at the film forming unit and is configured to measure a vapor concentration of the material gas discharged to the substrate; and a controller configured to control a film forming condition based on a measurement result from the detector. Further, the detector may include at least one of an optical sensor, a mass spectrometer, a vacuum gauge capable of measuring an absolute pressure (for example, capacitance manometer (hereinafter, simply referred to as “CM”)) and an ionization vacuum gauge (for example, Tough Gauge). Furthermore, the detector may be configured to detect a component of the material gas.

The controller may be configured to control one or more of a carrier gas flow rate, a heater temperature in a material gas generating unit, a material supply amount, a substrate moving speed, a substrate temperature and a chamber pressure.

In accordance with another aspect of the illustrative embodiment, there is provided an evaporating method of forming a thin film on a substrate by a vapor deposition process. The evaporating method includes measuring a vapor concentration of a material gas discharged to the substrate by a detector; and controlling a film forming condition based on a measurement result from the detector. Here, the film forming condition may be one or more of a carrier gas flow rate, a heater temperature in a material gas generating unit, a material supply amount, a substrate moving speed, a substrate temperature and a chamber pressure. Further, the detector may include at least one of an optical sensor, a mass spectrometer, a vacuum gauge capable of measuring an absolute pressure and an ionization vacuum gauge.

### Effect of the Invention

As stated above, in accordance with the illustrative embodiments, it is possible to provide an evaporating apparatus capable of controlling a thickness of a thin film before forming the thin film on a substrate G or while (on a real time basis) forming the thin film on the substrate G. Accordingly, the thin film of a required thickness can be formed on the substrate accurately and efficiently. Thus, a yield rate can be improved.

### BRIEF DESCRIPTION OF THE DRAWINGS

FIG. 1 is a diagram illustrating a conventional evaporating apparatus.

FIG. 2 provides diagrams for describing a manufacturing process of an organic EL device A.

FIG. 3 is a side cross sectional view of an evaporating apparatus.

FIG. 4 is a side cross sectional view of an evaporating apparatus in accordance with a second illustrative embodiment.

FIG. 5 is a side cross sectional view of an evaporating apparatus in accordance with a third illustrative embodiment.

FIG. 6(a) is a side cross sectional view of an evaporating apparatus in accordance with a fourth illustrative embodiment and FIG. 6(b) is a diagram illustrating a vacuum gauge.

FIG. 7 is a diagram illustrating a first modification example.

FIG. 8 is a diagram schematically illustrating an evaporating apparatus in accordance with a second modification example.

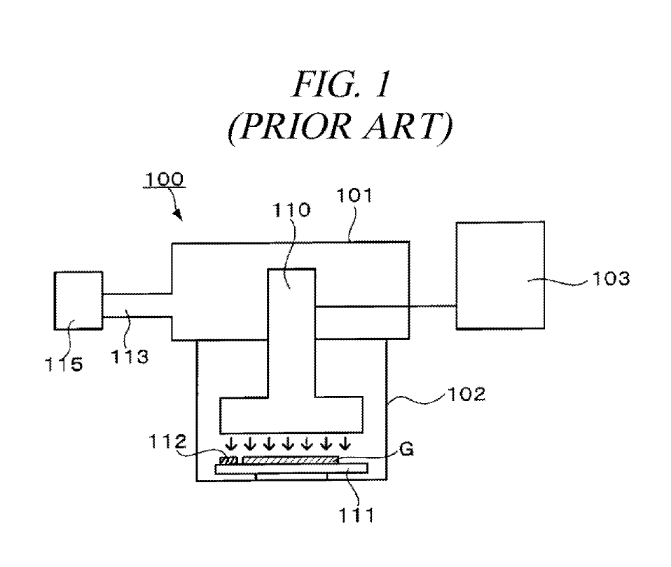

### EXPLANATION OF CODES

1, 50: Evaporating apparatus
10: Anode layer
11: Light emitting layer
12: Cathode layer
13: Sealing film layer
20, 51: Processing chamber
21: Substrate processing chamber
22, 56: Evaporating head
23, 54: Supporting table
25: Exhaust line
26: Vacuum pump
29: Material inlet path
30: Material gas generating unit
30a: Carrier gas controller
30b: Material supply controller
30c: Material vaporization controller
31: Heater
33: Film thickness sensor
40: Transmission window
41, 61: Optical sensor
42: Controller
43: Mass spectrometer
45: Ionization vacuum gauge
46: Vacuum gauge
47: Metal diaphragm
48: Electrode
52: Gate valve
55: Rail
57: Material source
58: Material supply line
A: Organic EL device
G: Substrate

### BEST MODE FOR CARRYING OUT THE INVENTION

Hereinafter, illustrative embodiments will be described in detail with reference to the accompanying drawings. In the specification and drawings, same parts having substantially same function and configuration will be assigned same reference numerals, and redundant description will be omitted. In the following, the illustrative embodiments will be described for the case of manufacturing an organic EL device using an organic material.

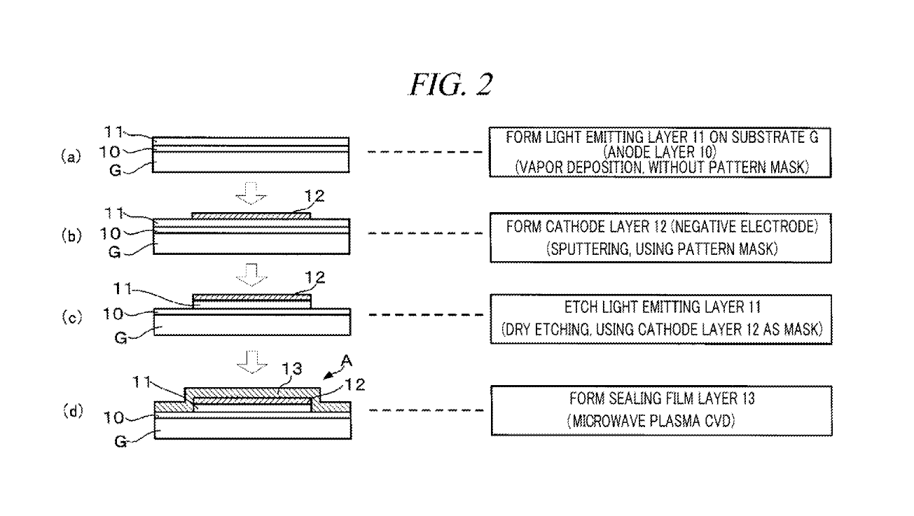

FIG. 2 provides diagrams for describing a manufacturing process of an organic EL device A manufactured by various types of film forming apparatuses including an evaporating apparatus 1 in accordance with an illustrative embodiment. As depicted in FIG. 2(a), there is prepared a substrate G having a top surface on which an anode (positive electrode) layer 10 is formed. The substrate G is made of a transparent material such as, but not limited to, glass. The anode layer 10 is made of a transparent conductive layer such as, but not limited to, ITO (Indium Tin Oxide). The anode layer 10 may be formed on the top surface of the substrate G by, e.g., a sputtering method.

First, as illustrated in FIG. 2(a), a light emitting layer (organic layer) 11 is formed on the anode layer 10 by a vapor deposition process. The light emitting layer 11 has a multi-layered structure including, for example, a hole transport layer, a non-light emitting layer (electron block layer), a blue-light emitting layer, a red-light emitting layer, a green-light emitting layer and an electron transport layer that are stacked on top of each other.

Then, as illustrated in FIG. 2(b), a cathode (negative electrode) layer 12 made of, but not limited to, Ag or Al is formed on the light emitting layer 11 by, e.g., a sputtering method using a mask.

Subsequently, as shown in FIG. 2(c), the light emitting layer 11 is patterned by performing, e.g., a dry etching on the light emitting layer 11 with the cathode layer 12 as a mask.

Thereafter, as depicted in FIG. 2(d), an insulating sealing film layer 13 made of, but not limited to, silicon nitride (SiN) is formed to cover surfaces of the light emitting layer 11 and the cathode layer 12 and an exposed portion of the anode layer 10. The sealing film layer 13 is formed by, e.g., a microwave plasma CVD method.

In the organic EL device A formed through the above process, by applying a voltage between the anode layer 10 and the cathode layer 12, the light emitting layer 11 emits light. Such an organic EL device A may be applicable to, but not limited to, a display device or a surface luminescent device (light device, light source, or the like). Besides, the organic EL device may also be applied to various kinds of electronic devices.

Now, evaporating apparatuses 1 in accordance with a first to a fourth illustrative embodiment will be described. In the evaporating apparatuses 1 in accordance with the first to fourth illustrative embodiments, an optical sensor, a mass spectrometer, an ionization vacuum gauge and a vacuum gauge (e.g., a capacitance manometer (CM)) capable of measuring an absolute pressure are used as a detector configured to detect a vapor concentration of an organic material gas (hereinafter, simply referred to as a “material gas”), respectively.

### First Illustrative Embodiment

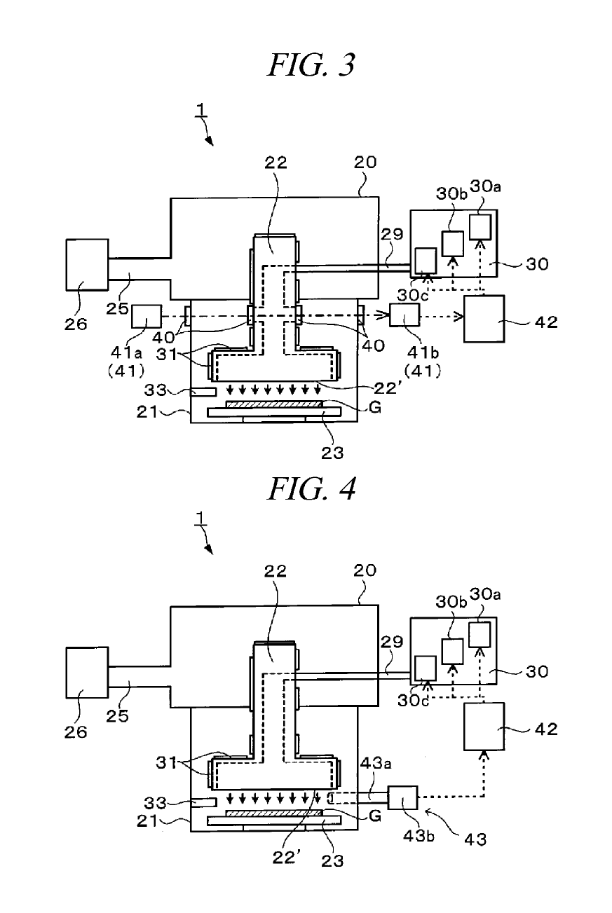

FIG. 3 is a side cross sectional view illustrating an evaporating apparatus 1 in accordance with the first illustrative embodiment. The evaporating apparatus 1 is used in the above-described vapor deposition process of FIG. 2(a). In this illustrative embodiment, an optical sensor 41 using, e.g., Fourier transform infrared spectroscopy (FTIR) is used as a detector configured to detect a vapor concentration of a material gas, for example. In a typical evaporating apparatus, there may be provided a plurality of evaporating heads, each of which is configured to discharge an organic material gas on a substrate G, in order to form a plurality of organic layers such as a hole transport layer, a non-light emitting layer (electron block layer), a blue-light emitting layer, a red-light emitting layer, a green-light emitting layer and an electron transport layer. However, the evaporating apparatus 1 shown in FIG. 3 is described to have a single evaporating head, for example.

As illustrated in FIG. 3, the evaporating apparatus 1 includes a processing chamber 20 and a substrate processing chamber 21 as a film forming unit configured to perform a film forming process. An evaporating head 22 is provided to be extended over the processing chamber 20 and the substrate processing chamber 21. The substrate processing chamber 21 is provided under the processing chamber 20. A supporting table 23 is provided within the substrate processing chamber 21 to support a substrate G with a film formation target surface of the substrate G facing upward (in a face-up state). Here, the evaporating head 22 is disposed such that a material gas discharging surface 22′ (opening surface) of the evaporating head 22 faces the top surface (film formation target surface) of the substrate G. Further, the processing chamber 20 communicates with a vacuum pump 26 via an exhaust line 25. During the film formation, the processing chamber 20 is evacuated to vacuum.

The evaporating head 22 is connected to a material gas generating unit 30 via a material inlet path 29 through which an organic material gas is introduced into the evaporating head 22. Here, the material gas generating unit 30 includes a non-illustrated heater configured to heat the organic material. A material gas heated and generated in the material gas generating unit 30 is introduced into the evaporating head 22 through the material inlet path 29. Then, the material gas is discharged to the substrate G from the evaporating head 22. Further, the material gas generating unit 30 also includes a carrier gas controller 30a configured to control a flow rate of a carrier gas; a material supply controller 30b configured to control a supply amount of the organic material; and a material vaporization controller 30c configured to control a vaporization amount of the organic material. Further, the evaporating head 22 is provided with heaters 31, and the organic material gas vaporized in the material gas generating unit 30 and introduced into the evaporating head 22 are heated to a temperature at which the organic material gas would not be precipitated within the evaporating head 22.

Also, for example, a film thickness sensor 33 is provided within the substrate processing chamber 21. The film thickness sensor 33 is configured to irradiate light to a thin film and to measure a thickness of the thin film from a Raman spectrum intensity of the reflected light from the thin film. With this configuration, it is possible to measure a thickness of a thin film formed on the substrate G whenever necessary.

Further, transmission windows 40 that transmit light are provided on both lateral sides of the evaporating head 22 and on both lateral sides of the substrate processing chamber 21. The transmission windows 40 may be made of, but not limited to, calcium fluoride. A light emitting unit 41a and a light receiving unit 41b of the optical sensor 41 are provided on both lateral sides outside the substrate processing chamber 21, respectively. An infrared ray is transmitted to an inside of the evaporating head 22 from the light emitting unit 41a of the optical sensor 41 through the transmission windows 40, and the transmitted infrared ray is received by the light receiving unit 41b. By comparing the light at the time of emission and the light at the time of reception, a gas state (concentration/component/spectrum of gas) within the evaporating head 22 can be detected. Here, by way of example, Fourier transform infrared spectroscopy (FTIR) configured to measure a light absorption amount by using an infrared ray may be considered as the optical sensor 41. The illustrative embodiment, however, may not be limited thereto, and an atomic absorption spectroscopy or a nondispersive infrared analysis (NDIR) may also be used. Further, instead of detecting a gas state within the evaporating head 22, it may be also possible to provide a gas branch line or an attracting line on the way of a material supply line and to detect a gas state therein.

The evaporating apparatus 1 further includes a controller 42 configured to output an instruction signal to the material gas generating unit 30 based on the gas state within the evaporating head 22 which is detected by the optical sensor 41 (light receiving unit 41b). Based on the instruction outputted from the controller 42, the flow rate of the carrier gas is controlled by the carrier gas controller 40a and the supply amount of the material is controlled by the material supply controller 30b. Further, based on the instruction outputted from the controller 42, the amount of the vaporized material is controlled in the material vaporization controller 30c. Accordingly, a required amount of material can be introduced into the evaporating head 22. Through this control, the thickness of the thin film formed on the substrate G is controlled.

Further, the thickness of the thin film formed on the substrate G may be varied depending on a moving speed of the substrate G, a temperature of the substrate G and an internal pressure of the processing chamber 20. Accordingly, by varying the moving speed of the substrate G, the temperature of the substrate G and the internal pressure of the processing chamber 20 based on the gas state within the evaporating head 22 detected by the optical sensor 41, the thickness of the thin film formed on the substrate G can also be controlled.

For the control of the thickness of the thin film formed on the substrate G, reference data are obtained by measuring through the film thickness sensor 33 under the condition where a material gas temperature (amount of vaporized material), a carrier gas flow rate and a material supply amount are set to be preset values in advance. Based on these reference data, database (or calibration curve) is obtained. By comparing and analyzing the database and measurement data obtained by the optical sensor 41 during an actual film forming process, a vapor concentration or an amount of the material gas may be calculated. In this way, the thickness of the thin film on the substrate G may be controlled. At this time, if the preset film forming conditions set based on the reference data in the database and actual film forming conditions for the substrate G are different, by considering a difference in the set conditions and the current film forming conditions (e.g., a difference between a required film thickness and a current film thickness, a partial pressure of the material gas within the substrate processing chamber, and the like), the thickness of the thin film may be controlled. That is, a thickness of a thin film to be formed on the substrate G is previously determined based on the conditions (a material gas temperature, a carrier gas flow rate, a material supply amount, etc.) set at the time of starting the film forming process. Then, if the thickness of a thin film actually formed on the substrate G is different from the previously determined thickness, the above-described film thickness control is performed immediately (on a real time basis), so that the thickness of the thin film formed on the substrate G can be controlled to the previously determined thickness.

As a method for controlling the film thickness, when the detected vapor concentration of the material gas by the optical sensor 41 is different from the preset concentration, the amount of the material gas introduced into the evaporating head 22 is adjusted by changing the flow rate of the carrier gas. Further, the amount of the material gas generated and vaporized in the material gas generating unit may be adjusted by controlling a supply amount of the material gas and a temperature of a vaporizing unit. More specifically, there is defined a threshold value corresponding to a deviation from the preset value. If a measurement value is larger than the threshold value, the material gas may be controlled by varying the temperature of the vaporizing unit. On the other hand, if a measurement value is smaller than the threshold value, it may be desirable to control the material gas just by adjusting the carrier gas flow rate without varying the temperature of the vaporizing unit. Since the amount of the material gas is very sensitive to a temperature variation of the vaporizing unit, a vaporization amount may be greatly changed even if the temperature variation is very small. As a result, a film forming rate or a film thickness may be greatly changed. Thus, the method of varying the temperature of the vaporizing unit may not be suitable for precise control. When the measurement value is smaller than the threshold value, it may be desirable to control the thickness of the thin film formed on the substrate G by adjusting, e.g., the carrier gas flow rate instead of by varying the temperature of the vaporizing unit. Controlling the film thickness through the carrier gas flow rate is also advantageous in that it has high reactivity.

Further, in accordance with the present illustrative embodiment, the vapor concentration of the material gas within the evaporating head 22 is measured frequently (on a real time basis) by the optical sensor 41. Through the above-described control of the vapor concentration of the material gas, the vapor concentration of the material gas within the evaporating head 22 is maintained such that a required thickness of the thin film formed on the substrate G is obtained at a certain film forming rate (film forming amount per unit time).

It may be considered to control the film forming rate and the thickness of the thin film formed on the substrate G by varying the moving speed of the substrate G. To elaborate, when the vapor concentration of the material gas discharged from the evaporating head 22 is high, in order to maintain the thickness of the thin film formed on the substrate G to the preset thickness, it may be considered to reduce the amount of the material gas discharged to a unit area of the substrate G by increasing the moving speed of the substrate G within the processing chamber 20. Alternatively, it may be also considered to increase the temperature of the substrate G or to increase the internal pressure of the processing chamber 20, thus making it difficult to facilitate film formation on the substrate G. On the other hand, when the vapor concentration of the material gas detected by the optical sensor 41 is lower than the preset concentration, it may be considered to decrease the moving speed of the substrate G, to decrease the temperature of the substrate G or to decrease the internal pressure of the processing chamber 20.

In the evaporating apparatus 1 having the above-described configuration, the organic material gas introduced from the material supplying unit 30 is discharged from the evaporating head 22, and a thin film is formed on the top surface of the substrate G. In this case, the concentration/component/spectrum of the organic material gas introduced in the evaporating head 22 is measured by the optical sensor 41. A concentration of the material gas at a certain position within the evaporating head 22 and a thickness of an organic thin film formed on the substrate G at that time have a certain correlation if the other conditions are same. Thus, by detecting the concentration/component/spectrum of the organic material gas within the evaporating head 22 and controlling the conditions such as the above-described material gas generation amount in the material gas generating unit 30 based on the detection result of the concentration/component/spectrum of the organic material gas, the thickness and the film forming rate of the organic film formed on the substrate G are controlled. Further, since the concentration/component/spectrum of the organic material gas within the evaporating head 22 is frequently measured (on a real time basis) while the film formation on the substrate G is being performed, it becomes possible to control the thickness of the thin film while forming the thin film.

That is, by varying a carrier gas flow rate, a heater temperature of the material gas generating unit, a material supply amount, a substrate moving speed, a substrate temperature, a chamber pressure, etc., in the evaporating apparatus 1 based on the measurement results of the concentration of the organic material gas, a film forming condition for the substrate G can be varied and an organic thin film having a required thickness can be formed. Further, it becomes possible to control a thickness of a thin film actually formed on the substrate G by measuring the concentration/component/spectrum of the material gas introduced into the evaporating head 22 without having to form a thin film on the substrate G or a dummy substrate in advance. Thus, a film forming process on the substrate G can be started efficiently. Further, since a thickness of the thin film can be controlled while concurrently forming a film on the substrate G, it is possible to prevent a thin film from having a thickness other than a required thickness. As a result, it is also possible to improve a yield rate.

Moreover, when a difference between a thickness of a thin film calculated from a concentration of an organic material gas and a required thickness of a thin film is great, it may be desirable to vary a material gas temperature (heater temperature of the material gas generating unit) or a carrier gas flow rate. Meanwhile, if a difference between the thickness of the thin film calculated from the concentration of the organic material gas and the required thickness of the thin film is small, it may be desirable to control the film thickness by varying a carrier gas flow rate or a substrate moving speed. Since a temperature variation directly leads to a variation of a vapor concentration of a material gas, even a minor change in the material gas temperature may have a great influence on the thickness of the thin film formed on the substrate. Meanwhile, a variation in the substrate moving speed may not have a great effect upon the thickness of the thin film formed on the substrate. Further, the responsiveness to film thickness is high.

### Second Illustrative Embodiment

FIG. 4 is a side cross sectional view illustrating an evaporating apparatus 1 in accordance with a second illustrative embodiment. The evaporating apparatus 1 may be used in the above-described vapor deposition process of FIG. 2(a). In accordance with the second illustrative embodiment, a mass spectrometer 43 implemented by, e.g., a quadrupole mass spectrometer (Q-mass) is used as a detector configured to measure a vapor concentration of a material gas. Further, in FIG. 4, the other components except the mass spectrometer in the second illustrative embodiment are the same as those of the first illustrative embodiment and have the same configurations and functions as those thereof. Thus, the same parts will be assigned same reference numerals, and redundant description will be omitted.

As illustrated in FIG. 4, in the substrate processing chamber 21, a measuring unit 43a is disposed in a vicinity of the material gas discharging surface 22′ of the evaporating head 22. A controller unit 43b connected to the measuring unit 43a is provided at the outside of the substrate processing chamber 21. The mass spectrometer 43 includes the measuring unit 43a and the controller unit 43b. In the mass spectrometer 43 implemented by, e.g., a quadrupole mass spectrometer (Q-mass), the measuring unit 43a ionizes a material gas discharged from the evaporating head 22 by bringing electrons into contact with the material gas and measures a mass distribution of the material gas. Thus, a quality and a quantity of the material gas are detected. As for the position of the measuring unit 43a, the measuring unit 43a may be provided within the evaporating head 22 or at a material gas transport path. However, accurate detection may not be performed depending on a pressure band, or sensitivity may be deteriorated due to adhesion of the material gas to the measuring unit 43a. Thus, it may be desirable to provide the measuring unit 43a in the vicinity of the material gas discharging surface 22′ within the substrate processing chamber 21, as illustrated in FIG. 4.

Measurement data obtained by the measuring unit 43a is sent to a controller 42 from the controller unit 43b. Under the control of the controller 42, a temperature of the material gas (vaporization amount of the material gas), a supply amount of the material gas and a flow rate of a carrier gas in the material generating unit 30 are controlled by the material vaporization controller 30c, the material supply controller 30b and the carrier gas controller 30a, respectively. The control of the temperature (vaporization amount) and the supply amount of the material gas and the flow rate of the carrier gas is performed in the same manner as elaborated in the first illustrative embodiment. Thus, redundant description will be omitted here.

By changing one or more conditions among the temperature (vaporization amount) of the material gas, the supply amount of the material gas and the flow rate of the carrier gas based on the measurement data obtained by the mass spectrometer 43, a vapor concentration of the material gas discharged to a substrate G is controlled. As a result, an organic thin film having a required thickness can be formed on the substrate G. Further, it becomes possible to control the thickness of the thin film actually formed on the substrate G just by measuring the material gas introduced into the evaporating head 22 through the mass spectrometer 43 without having to perform a film formation on the substrate G or a dummy substrate in advance. Thus, a film forming process on the substrate G can be started efficiently.

### Third Illustrative Embodiment

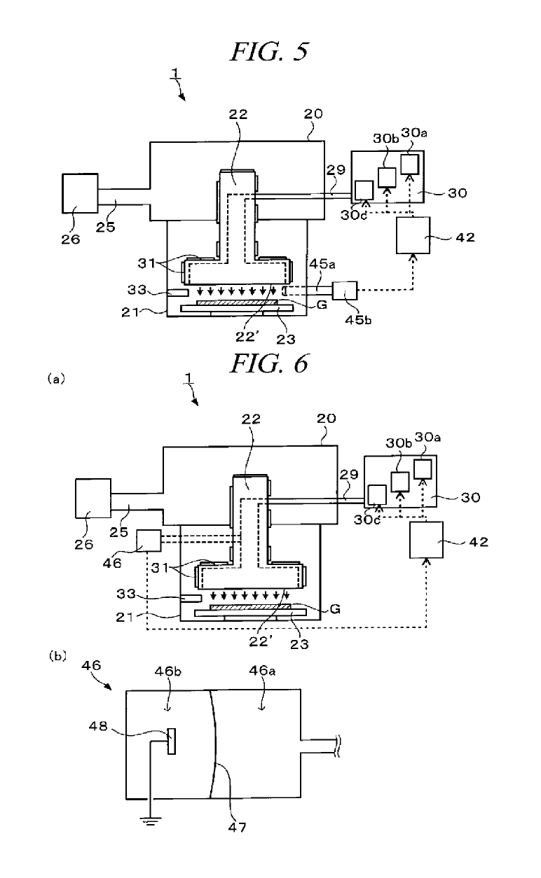

FIG. 5 is a side cross sectional view of an evaporating apparatus 1 in accordance with a third illustrative embodiment. The evaporating apparatus 1 may be used in the above-described vapor deposition process of FIG. 2(a). In accordance with the third illustrative embodiment, an ionization vacuum gauge 45 implemented by, e.g., a Tough Gauge (TA) (manufactured by Ampere Inc.) is used as a detector configured to measure a vapor concentration of a material gas. In FIG. 5, the other components except the ionization vacuum gauge 45 in the second illustrative embodiment are the same as those of the first illustrative embodiment and have the same configurations and functions as those thereof. Thus, the same parts will be assigned same reference numerals, and redundant description will be omitted.

As depicted in FIG. 5, a measuring unit 45a is provided in the vicinity of the material gas discharging surface 22′ of the evaporating head 22 in the substrate processing chamber 21. A controller unit 45b connected to the measuring unit 45a is disposed at the outside of the substrate processing chamber 21. The ionization vacuum gauge 45 includes the measuring unit 45a and the controller unit 45b. The measuring unit 45a of the ionization vacuum gauge 45 is configured to measure a vacuum degree (internal pressure) within the substrate processing chamber 21 which is maintained substantially in a vacuum state.

In the measurement with the ionization vacuum gauge 45, a vacuum degree (internal pressure) of the substrate processing chamber 21 in a state where a material gas is not introduced in the substrate processing chamber 21, i.e., in a state where an organic material is not heated and generated in the material gas supplying unit 30 is first measured (background measurement). Then, a vacuum degree (internal pressure) of the substrate processing chamber 21 after a material gas is introduced into the substrate processing chamber 21 from the material gas generating unit 30 through the evaporating head 22 is measured. By calculating a difference between the vacuum degrees before and after introducing the material gas, a variation in the vacuum degree within the substrate processing chamber 21 by the material gas is calculated, and a partial pressure of the material gas is calculated. The partial pressure of the material gas has correlation with a vapor concentration of the material gas introduced into the substrate processing chamber 21. Accordingly, by measuring the partial pressure of the material gas continuously by the ionization vacuum gauge 45, a variation in the vapor concentration of the material gas introduced in the substrate processing chamber 21 is measured. Here, the ionization vacuum gauge 45 (especially, the measuring unit 45a) may be provided at any positions within the substrate processing chamber 21. In order to accurately measure the partial pressure of the material gas, however, it may be desirable to provide the ionization vacuum gauge 45 (especially, the measuring unit 45a) in the vicinity of the material gas discharging surface 22′ of the evaporating head 22, within the evaporating head 22, within a gas transport path, or the like.

Measurement data obtained by the measuring unit 45a is sent to a controller 42 from the controller unit 45b. Under the control of the controller 42, a temperature of the material gas (a vaporization amount of the material gas), a supply amount of the material gas and a flow rate of a carrier gas in the material generating unit 30 are controlled by the material vaporization controller 30c, the material supply controller 30b and the carrier gas controller 30a, respectively. The control of the temperature (vaporization amount) and the supply amount of the material gas and the flow rate of the carrier gas is performed in the same manner as elaborated in the first illustrative embodiment. Thus, redundant description will be omitted here.

By changing one or more conditions among the temperature (vaporization amount) of the material gas, the supply amount of the material gas and the flow rate of the carrier gas based on the measurement data obtained by the ionization vacuum gauge 45, a vapor concentration of the material gas discharged to a substrate G is controlled. As a result, an organic thin film having a required thickness can be formed on the substrate G. Further, it becomes possible to control the thickness of the thin film actually formed on the substrate G just by measuring the material gas introduced into the evaporating head 22 through the ionization vacuum gauge 45 without having to perform a film formation on the substrate G or a dummy substrate in advance. Thus, a film forming process on the substrate G can be started efficiently.

### Fourth Illustrative Embodiment

FIG. 6(a) is a side cross sectional view of an evaporating apparatus 1 in accordance with a fourth illustrative embodiment. The evaporating apparatus 1 may be used in the above-described vapor deposition process of FIG. 2(a). FIG. 6(b) is a diagram illustrating a vacuum gauge 46 used in the evaporating apparatus 1 in accordance with the fourth illustrative embodiment. In accordance with the fourth illustrative embodiment, the vacuum gauge 46 capable of measuring an absolute pressure is used as a detector configured to measure a vapor concentration of a material gas. The vacuum gauge 46 may be implemented by, e.g., a capacitance manometer (hereinafter, simply referred to as “CM”). Further, in FIG. 6, the other components except the vacuum gauge 46 in the fourth illustrative embodiment are the same as those of the first illustrative embodiment and have the same configurations and functions as those thereof. Thus, the same parts will be assigned same reference numerals, and redundant description will be omitted.

As illustrated in FIG. 6(a), the vacuum gauge 46 is provided to communicate with the inside of the evaporating head 22. The CM used as the vacuum gauge 46 is one of diaphragm vacuum gauges capable of measuring an absolute pressure. A thin metal plate disposed within the CM is elastically deformed by a pressure difference, and such a deformation is detected as an electrostatic capacitance. As depicted in FIG. 6(b), the vacuum gauge 46 has therein two rooms 46a and 46b separated with a metal diaphragm 47 therebetween. One room 46a communicates with an internal space of the evaporating head 22, while an insulated electrode 48 is disposed within the other room 46b. With respect to a pressure within the room 46b where the electrode 48 is disposed, the metal diaphragm 47 is deformed by a pressure difference between the two rooms 46a and 46b, so that an electrostatic capacitance is varied according to a distance between the insulated electrode 48 and the metal diaphragm 47. The deformation amount of the metal diaphragm 47 is obtained by using a variation in the electrostatic capacitance. Then, by converting the deformation amount into a pressure, a pressure within the evaporating head 22 (within the processing chamber 20) can be calculated. By measuring the pressure within the evaporating head 22 appropriately, a vapor concentration of a material gas flowing therein is measured. Further, the vacuum gauge 46 implemented by the CM may be widely used in measuring a pressure in the range, e.g., from an atmospheric pressure to about 10 mPa (about 0.1 mTorr).

While various aspects and embodiments have been described herein, other aspects and embodiments will be apparent to those skilled in the art. The various aspects and embodiments disclosed herein are for the purposes of illustration and are not intended to be limiting. Therefore, the true scope of the disclosure is indicated by the appended claims rather than by the foregoing description, and it shall be understood that all modifications and embodiments conceived from the meaning and scope of the claims and their equivalents are included in the scope of the disclosure.

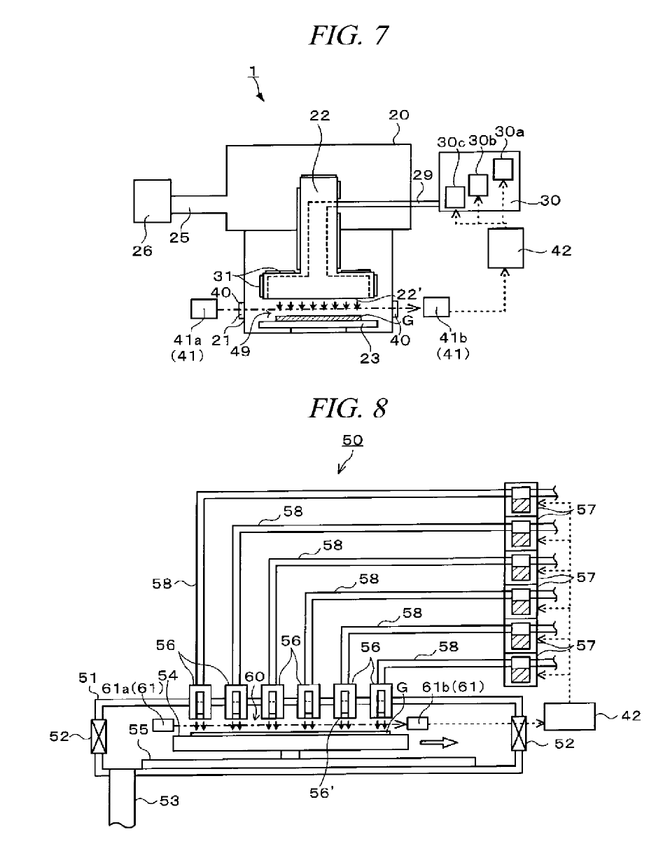

By way of example, in the above-described first illustrative embodiment, light of the optical sensor 41 is transmitted through the inside of the evaporating head 22, and the transmission windows 40 are provided on both lateral sides of the evaporating head 22. However, the light transmission path need not be limited to the inside of the evaporating head 22, but may be any place where an organic material gas can be detected sufficiently. In this regard, FIG. 7 illustrates a first modification example. In FIG. 7, the evaporating head 22 is viewed from a transfer direction of a substrate G (an orthogonal direction to a paper plane).

As shown in FIG. 7, in this modification example, light from the optical sensor 41 passes through a gap between the material gas discharging surface 22′ of the evaporating head 22 and the top surface of the substrate G. That is, the optical sensor 41 is configured to pass the light through a gap 49 between the material gas discharging surface 22′ of the evaporating head 22 of an evaporating apparatus 1 and the top surface of the substrate G in the orthogonal direction to the transfer direction of the substrate G. The optical sensor 41 configured to detect a concentration, a component and a spectrum of an organic material gas discharged from the evaporating head 22 is provided at the substrate processing chamber 21, as in the first illustrative embodiment. A material gas supply amount in the material generating unit 30 is controlled in response to an instruction signal from this optical sensor 41 as in the first illustrative embodiment.

Further, the above first to fourth illustrative embodiments have been described for the configuration where only one evaporating head 22 is provided. Typically, however, in vapor deposition of organic films, six evaporating heads 22 may be provided in order to form a hole transport layer, a non-light emitting layer (electron block layer), a blue-light emitting layer, a green light-emitting layer and an electron transport layer consecutively on a substrate G. In the following, with reference to an accompanying drawing, there will be explained a second modification example where six evaporating heads 22 are provided. Here, although the second modification example will be described for the case of using an optical sensor 61 as a detector configured to detect a vapor concentration of a material gas, any detectors described in the first to fourth illustrative embodiments may be employed.

FIG. 8 is a diagram schematically illustrating an evaporating apparatus 50 in accordance with the second modification example. The evaporating apparatus 50 shown in FIG. 8 is configured to form a light emitting layer 11 shown in FIG. 2(a) by the vapor deposition process.

The evaporating apparatus 50 includes a hermetically sealed processing chamber 51. The processing chamber 51 has a rectangular parallelepiped shape of which lengthwise direction is coincident with a transfer direction of a substrate G. A front side and a back side of the processing chamber 51 are connected to other film forming apparatuses or the like via gate valves 52.

An exhaust line 53 including a vacuum pump (not shown) is connected to a bottom surface of the processing chamber 51 to depressurize the inside of the processing chamber 51. Further, a supporting table 54 configured to horizontally support thereon a substrate G is also provided within the processing chamber 51. The substrate G is mounted on the supporting table 54 with its top surface facing upward. On the top surface of the substrate G, there is formed the anode layer 10 in advance. The supporting table 54 is moved on a rail 55 disposed along the transfer direction of the substrate G, while transferring the substrate G thereon.

A multiple number of (six in FIG. 8) evaporating heads 56 are arranged at a ceiling surface of the processing chamber 51 in the transfer direction of the substrate G. A multiple number of material sources 57 configured to supply vapors (material gases) of film forming materials for forming the light emitting layer 11 are connected to the evaporating heads 56 via material supply lines 58, respectively. The substrate G supported on the supporting table 54 is transferred while the vapors of the film forming materials supplied from the material sources 57 are discharged from the respective evaporating heads 56. As a result, a hole transport layer, a non-light emitting layer, a blue-light emitting layer, a red-light emitting layer, a green-light emitting layer and an electron transport layer are formed on the top surface of the substrate in this sequence, As a result, the light emitting layer 11 is formed on the top surface of the substrate G.

When detection sensitivity by the optical detection is good, it may be possible to provide the optical sensor 61 (including a light emitting unit 61a at an upstream side of the substrate transfer direction and a light receiving unit 61b at a downstream side thereof) configured to pass light in the transfer direction of the substrate G as shown in FIG. 8. In such case, the optical sensor 61 may accurately distinguish and detect specific spectrums of the organic material gases discharged from the evaporating heads 56. Thus, concentrations of the organic material gases from the six evaporating heads 56 are detected at the same time, and control of the material gas supply can be performed based on the detection results. In accordance with the evaporating apparatus 50 of the second modification example, the six kinds of organic material gases discharged from the six evaporating heads can be detected simultaneously by the single optical sensor 61. Thus, the apparatus can be simplified and cost can be reduced.

That is, in the evaporating apparatus 50 having the multiple number of evaporating heads 56, by detecting concentrations/components/spectrums of the multiple kinds of organic material gases with the optical sensor 61, film forming conditions are specified. Then, by controlling the concentrations/components/spectrums of the organic material gases as in the above-described illustrative embodiment, the thicknesses of thin films formed on the substrate G can be controlled.

The above first to fourth illustrative embodiments have been described for the cases of respectively providing a single optical sensor, a single mass spectrometer, a single ionization vacuum gauge and a single vacuum gauge capable of measuring an absolute pressure as a detector in order to detect a vapor concentration of a material gas. When using the optical sensor 41, however, a sufficient optical path length needs to be secured within the evaporating head 22 or within the substrate processing chamber 21. In an evaporating apparatus 1 in which a sufficient optical path length cannot be obtained, sufficient detection sensitivity may not be obtained. Further, when using a Q-mass as the mass spectrometer 43, for example, a material gas may come into contact with a detection filament and the organic material may be precipitated on a surface of the detection filament. As a result, detection sensitivity may be degraded as times goes on. Moreover, when using the ionization vacuum gauge 45, if a partial pressure of a material gas within the evaporating head 22 or within the substrate processing chamber 21 is low, detection may not be performed successfully.

In view of the foregoing problems, it may be possible to use at least two of the optical sensor 41, the mass spectrometer 43, the ionization vacuum gauge 45 and the vacuum gauge 46 in order to measure a vapor concentration of a material gas with higher accuracy. Further, in addition to the optical sensor 41, the mass spectrometer 43, the ionization vacuum gauge 45 and the vacuum gauge 46, it may be also possible to use a quartz crystal microbalance (QCM) or a dummy substrate that has been conventionally used to measure a thickness of a thin film formed on a substrate G. A quartz crystal microbalance (QCM) may be disposed directly under the evaporating head, and correlation between a thickness of an actually formed thin film and a measurement value obtained by another detector may be investigated. In such a case, if the correlation is found to be out of a certain correlation, correction may be performed. Here, after using the quartz crystal microbalance (QCM) certain times, hot N₂ or UV may be irradiated thereto so that an organic film attached thereto may be removed.

Further, by way of example, at an initial state of film formation on a substrate G, control of a vapor concentration of a material gas may not be performed sufficiently. Thus, it may be considered to control a thickness of a thin film formed on the substrate G by using a quartz crystal microbalance (QCM) or a dummy substrate in addition to the optical sensor 41, the mass spectrometer 43, the ionization vacuum gauge 45 and the vacuum gauge 46 capable of measuring an absolute pressure. Then, if the film thickness is stabilized, only one or more of the optical sensor 41, the mass spectrometer 43, the ionization vacuum gauge 45 and the vacuum gauge 46 may be used without using the quartz crystal microbalance (QCM) or the dummy substrate.

Further, the above illustrative embodiments and modification examples have been described for the case of using an organic thin film by an organic material gas. However, the illustrative embodiments may not be limited thereto and may also be applicable to depositing a metal such as Li on a substrate.

### INDUSTRIAL APPLICABILITY

An evaporating apparatus in accordance with the illustrative embodiments may have many advantages when it is used in forming a light emitting film when manufacturing, e.g., an organic EL device.

1-4. (canceled)

5. An evaporating method of forming a thin film on a substrate by a vapor deposition process, the evaporating method comprising:
measuring a vapor concentration of a material gas discharged to the substrate by a detector; and
controlling a film forming condition based on a measurement result from the detector.

6. The evaporating method of claim 5,
wherein the controlling of the film forming condition is performed by previously setting a film forming condition for forming the thin film of a required thickness on the substrate and by measuring a difference from the previously set film forming condition.

7. The evaporating method of claim 5,
wherein the film forming condition is one or more of a carrier gas flow rate, a heater temperature in a material gas generating unit, a material supply amount, a substrate moving speed, a substrate temperature and a chamber pressure.

8. The evaporating method of claim 5,
wherein the detector includes at least one of an optical sensor, a mass spectrometer, a vacuum gauge capable of measuring an absolute pressure and an ionization vacuum gauge.
